(19) United States
(12) Patent Application Publication
(10) Pub. No.: US 2008/0278185 A1
(43) Pub. Date: Nov. 13, 2008

(54) ELECTRICAL CONTACT DEVICE AND ITS MANUFACTURING PROCESS

(75) Inventor: Chih-Chung CHEN, Chu-Pei City (TW)

Correspondence Address: BROWDY AND NEIMARK, P.L.L.C.;624 NINTH STREET, NW, SUITE 300, WASHINGTON, DC, 20001-5303, US

(73) Assignee: MJC Probe Incorporation, Chu-Pei City (TW)

(21) Appl. No.: 11/964,369

(22) Filed: Dec. 26, 2007

(30) Foreign Application Priority Data
May 9, 2007 (TW) 96116552

(51) Int. Cl. G01R 1/067; H01R 43/16

(52) U.S. Cl. 324/754; 29/874

(57) ABSTRACT

A method of making an electrical contact device includes the step of (a) preparing a substrate, (b) forming a dielectric layer on a surface of the substrate and forming a well on the dielectric layer by means of a non-etching technique, (c) forming a first sacrifice layer in the well, (d) forming a second sacrifice layer on the dielectric layer and the first sacrifice layer and defining a probe body contour and forming a probe body metal layer in the probe body contour and then repeating this step once or several times to form a probe structure, and (e) removing the sacrifice layers to obtain the desired electrical contact device having the substrate and the probe structure.

### BACKGROUND OF THE INVENTION

1. Field of the Invention

The present invention relates generally to electrical contact devices and more particularly, to a method of making an electrical contact device.

2. Description of the Related Art

When testing IC chips, display panels, or other devices that require a temporary contact electrically, electrical contact devices shall be used for electrical connection with the test sample.

Taiwan patent application No. 94129539 discloses a similar design entitled “Electrical Contact Device for Probe Card”, which comprises a substrate having arranged thereon a circuitry subject to a predetermined pattern, and a plurality of probes installed in the surface of the substrate and electrically connected to the circuitry for contacting the device to be tested. To prevent disconnection of the probes from the substrate and to enhance the resistance power of the probes against elastic stress, wells are made on the surface of the substrate corresponding to the probes. By means of the space provided by the wells, the degree of elastic deformation of the probes is relatively increased, assuring impedance uniformity during contact of the probes with the test sample.

The aforesaid wells are directly formed on the surface of the substrate by means of etching. This etching procedure is complicated, resulting in low manufacturing speed. Therefore, this procedure is not in favor of mass production. Further, this etching procedure wastes many materials, thereby increasing the cost. Further, etching has a great process variation that lowers the yield rate and does not impart good reworkability.

### SUMMARY OF THE INVENTION

The present invention has been accomplished under the circumstances in view. It is therefore the primary objective of the present invention to provide a method of making an electrical contact device, which is easy and rapid to perform and has the benefits of low processing cost and good reworkability.

To achieve this objective of the present invention, the method of making an electrical contact device comprises the steps of (a) preparing a substrate; (b) forming a dielectric layer on a surface of the substrate and forming a well on the surface of the dielectric layer by means of a non-etching technique, (c) forming a first sacrifice layer in the well, (d) forming a second sacrifice layer on the dielectric layer and the first sacrifice layer, defining a probe body contour, forming a probe body metal layer in the probe body contour and then repeating this step once or several times to form a probe structure, and (e) removing the first sacrifice layer and the second sacrifice layer to obtain the desired electrical contact device having the probe structure and the substrate.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below and the accompanying drawings which are given by way of illustration only, and thus are not limitative of the present invention, and wherein:

FIGS. 1-12 are schematic drawings showing the steps of a method of making an electrical contact device in accordance with a first preferred embodiment of the present invention;

FIGS. 13-18 are schematic drawings showing the steps of a method of making an electrical contact device in accordance with a second preferred embodiment of the present invention;

FIGS. 19-21 are schematic drawings showing the steps of a method of making an electrical contact device in accordance with a third preferred embodiment of the present invention;

FIG. 22 is a schematic drawing showing an alternate form of the third preferred embodiment of the present invention;

FIGS. 23-26 are schematic drawings showing the steps of a method of making an electrical contact device in accordance with a fourth preferred embodiment of the present invention, and

FIGS. 27 and 28 are schematic drawings showing the steps of a method of making an electrical contact device in accordance with a fifth preferred embodiment of the present invention.

### DETAILED DESCRIPTION OF THE INVENTION

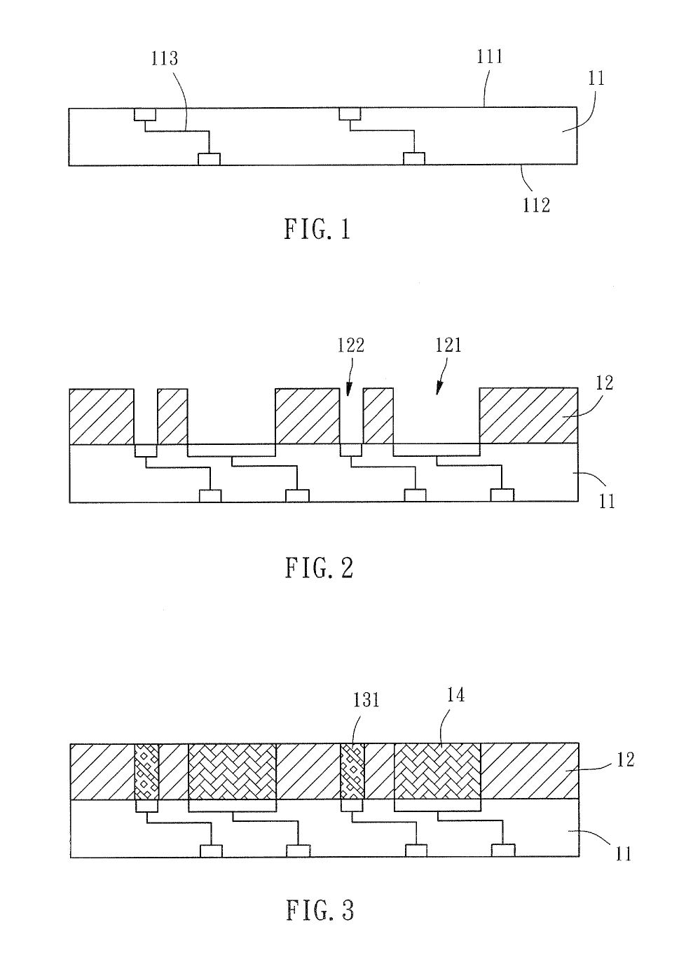

Referring to FIGS. 1-12, a method of making an electrical contact device in accordance with a first preferred embodiment of the present invention includes the steps of (a)-(j) as follows.

(a) Prepare a substrate 11, which has a first surface 111, a second surface 112 opposite to the first surface 111, a plurality of circuit layouts 113 arranged therein subject to a predetermined pattern and extending between the first surface 111 and the second surface 112, as shown in FIG. 1. Circuit layouts and contacts may be arranged on the first surface 111 and the second surface 112 for the mounting of necessary component parts or for the connection of probes.

(b) As shown in FIG. 2, form a dielectric layer 12 on the first surface 111 of the substrate 11 by means of micro processing technology from an electrically insulative material, for example, thick-film Photoresist. According to this embodiment, the dielectric layer 12 is formed by means of lithography and has wells 121 on the top and a plurality of locating portions in communication with the circuit layouts 113 at the first surface 11 of the substrate 11. The well 121 has a wall abutting with the surface of the dielectric layer 12. In this preferred embodiment, the locating portion is a connection groove 122 formed on the wall. The thick-film photoresist can be coated on the first surface 111 of the substrate 11, or bonded to the first surface 111 of the substrate 11 by means of compress molding.

(c) As shown in FIG. 3, implant a first probe body metal layer 131 in each connection groove 122 of the dielectric layer 12 and a first sacrifice layer 14 in each well 121 of the dielectric layer 12 by means of electroforming technology, and if necessary, leveling the first probe body metal layer 131 and the first sacrifice layer 14 to be flush with the dielectric layer 12 by means of mechanical grinding, chemical grinding, electrochemical machining, or chemical etching.

The aforesaid steps (b) and (c) may be repeated once or several times till the dielectric layer 12 and each first sacrifice layer 14 reach the desired size.

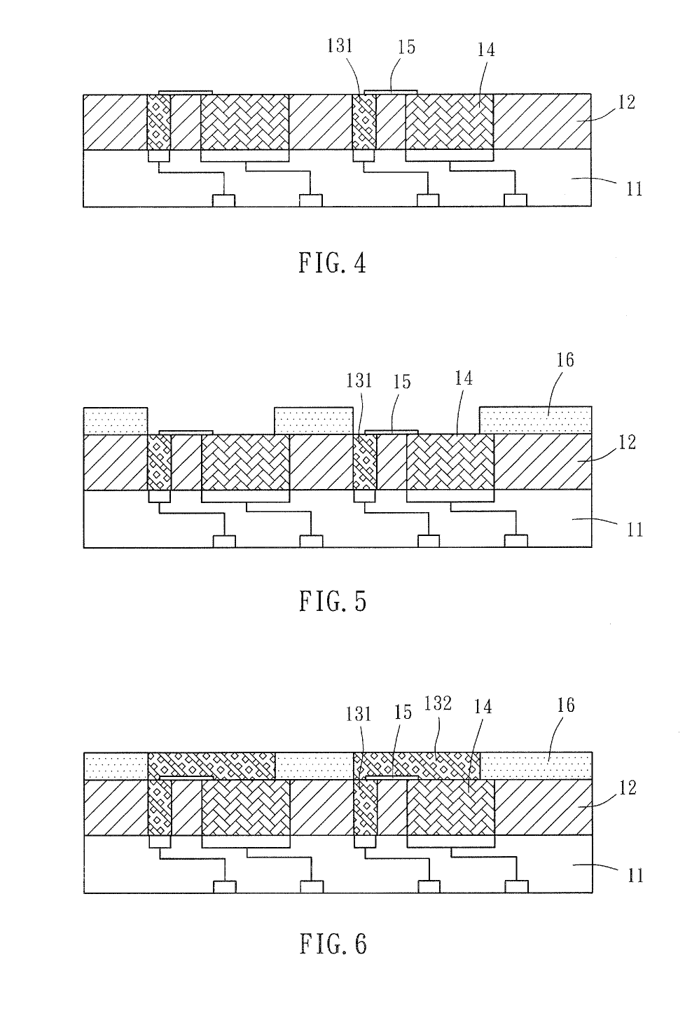

(d) As shown in FIG. 4, form a conducting layer 15 on the top side of the dielectric layer 12. According to this embodiment, the conducting layer 15 is processed through lithography and etching techniques to define a part or the whole of the desired probe body pattern, i.e., the conducting layer 15 is left in the area connected between the first sacrifice layer 14 in each well 121 and the first probe body metal layer 131 in each connection groove 122. Except lithography and etching techniques, the conducting layer 15 can be formed by patterning conducting material by means of metal lift-off process, printing process, lithography and electroplating techniques, lithography and chemical plating techniques, or fine spray-coating technique.

(e) As shown in FIG. 5, form a second sacrifice layer 16 on the top side of the dielectric layer 12 around the conducting layer 15 and the first probe body metal layer 131 and above the first sacrifice layer 14 and the dielectric layer 12. According to this embodiment, the second sacrifice layer 16 is formed of a strippable photoresist by means of lithography and processed through lithography to define a probe body contour.

(f) As shown in FIG. 6, form a conducting second probe body metal layer 132 in the probe body contour of the second sacrifice layer 16 by means of electroforming technique.

The aforesaid steps (e) and (f) may be repeated once or several times till that the second probe body metal layer 132 and the second sacrifice layer 16 reach the desired size.

Further, except forming the second probe body metal layer 132 by electroforming technique, step (e) may be omitted, i.e., the formation of the conducting layer 15 may be eliminated. In this case, a conducting substance may be deposited in the probe body contour of the second sacrifice layer 16 by means of chemical plating or filling-in technique directly to form the second probe body metal layer 132. If necessary, the aforesaid steps may be repeated several times till that the second probe body metal layer 132 and the second sacrifice layer 16 reach the desired size.

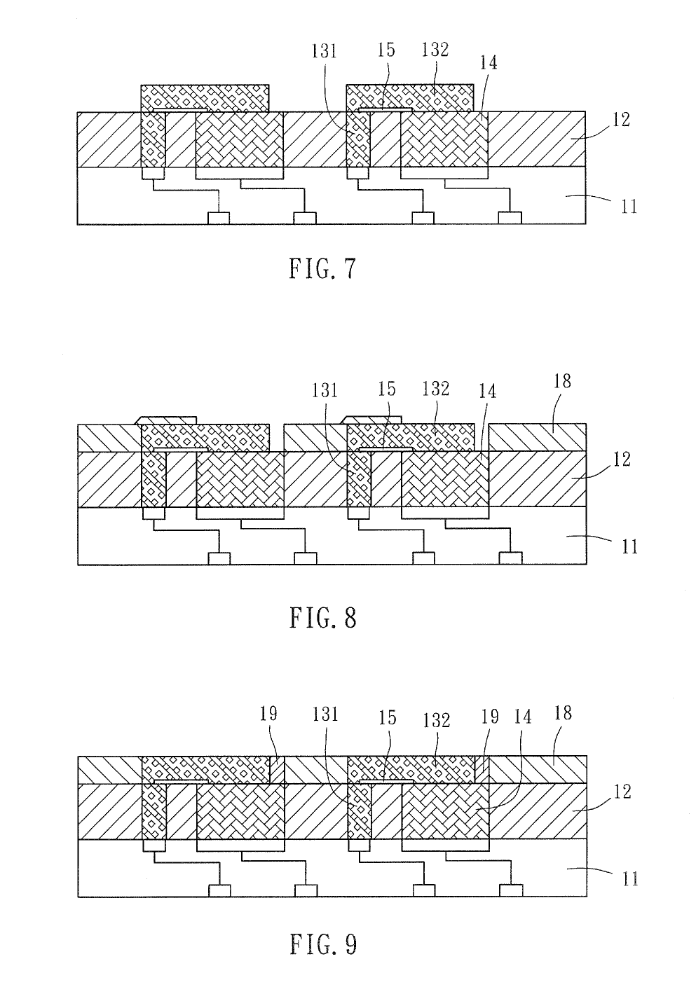

(g) Remove the second sacrifice layer 16, as shown in FIG. 7.

(h) As shown in FIG. 8, lay an insulative layer 18 of a dielectric material over the second probe body metal layer 132 above each connection groove 122 by means of, for example, lithography, to enhance the bonding strength between the second probe body metal layer 132 and the dielectric layer 12, leaving a crevice around the second probe body metal layer 132. Spray-coating, coating, vapor deposition, sputtering deposition, or electro deposition coating may also be employed to form the insulative layer 18.

(i) Use electro forming or filling-in technique to apply a strippable material to the crevice left in step (h), thereby forming a third sacrifice layer 19 as shown in FIG. 9. If necessary, level the surface of the third sacrifice layer 19 by means of mechanical grinding, chemical grinding, electrochemical machining, or chemical etching to have the third sacrifice layer 19 be flush with the insulative layer 18.

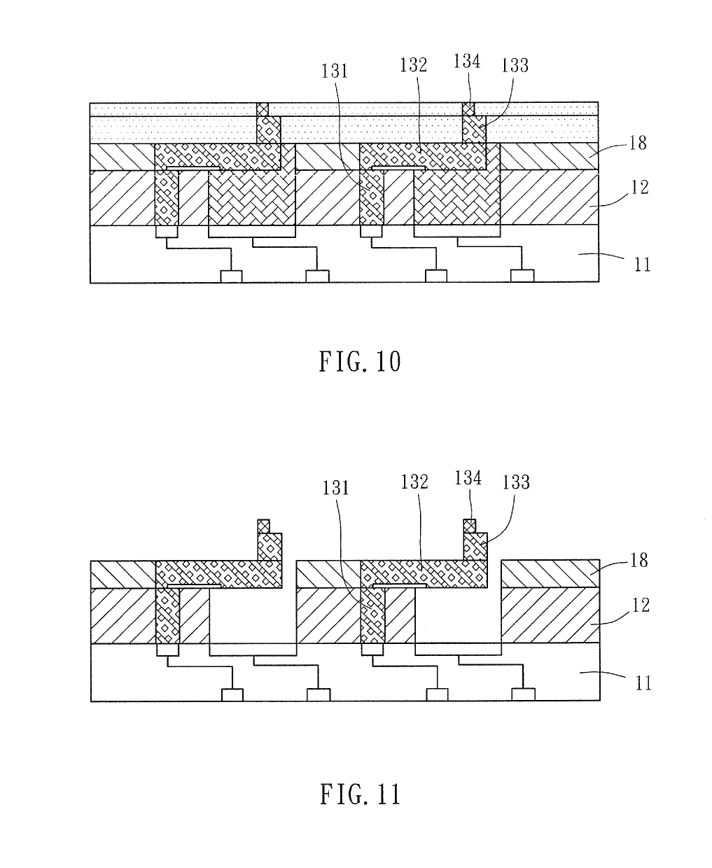

(j) Repeat steps (e) and (f) to form a third probe body metal layer 133 on the second probe body metal layer 132 and a fourth probe body metal layer 134 on the third probe body metal layer 133 as shown in FIG. 10.

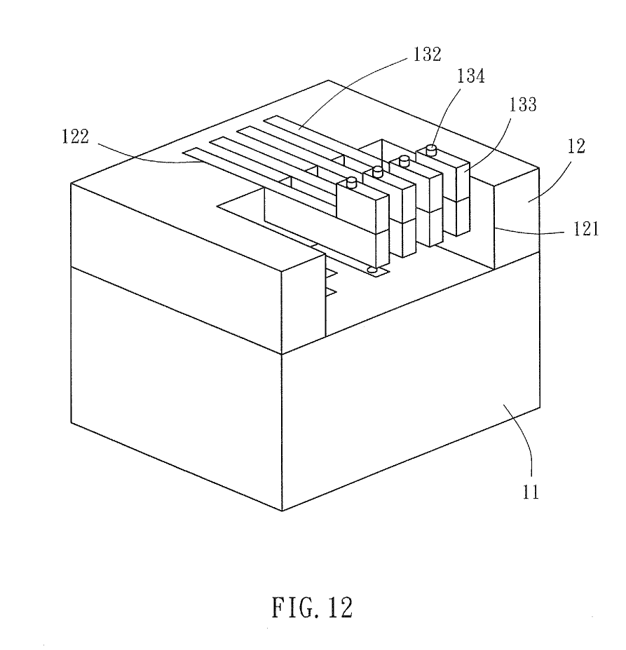

(k) Employ etching technique to remove the first sacrifice layer 14, the second sacrifice layer 16 and the third sacrifice layer 19, as shown in FIGS. 11 and 12. Thus, the fabrication of the electrical contact device is finished. After fabrication of the electrical contact device, the substrate 11 can be bonded to other devices by means of conventional mounting techniques.

Therefore, the method of making the electrical contact device of the present invention has the probe body metal layers 131-134 constitute the whole probe body of each designed probe in which the first probe body metal layer 131 is adapted to connect the detected electric properties to the circuit layouts 113; the first probe body metal layer 131 and the second probe body metal layer 132 are respectively filled in the dielectric layer 12 and the insulative layer 18 to enhance the connection tightness between each probe and the substrate; the second probe body metal layer 132 and the third probe body metal layer 133 constitute the body part of each probe; the fourth probe body metal layer 134 constitutes the probe tip of each probe. Further, the invention has one end of each probe positioned in the locating portion (connection groove) and the other end extended toward one associating well, so that each well 121 provides a space above the dielectric layer 12 for elastic deformation of the associating probe. The manufacturing process of the invention requires a less number of processing steps when compared to the conventional method of forming the wells by means of etching technology. Further, because of the use of non-etching techniques to form the desired wells and connection grooves, the invention eliminates the drawbacks of being not easy to control and high manufacturing cost of the conventional methods that employ etching steps, and also imparts good reworkability (etching process does not impart reworkability). Therefore, material selection for substrate according to the present invention is free from the limitation of etching process, i.e., the invention can select more suitable material for the substrate subject to the considerations of insulation and structural strength. For example, ceramic substrate can be used to improve the product performance and yield rate.

It is to be understood that the material for the first sacrifice layer 14 is not limited to the metal formed by electro forming technique. Vapor deposition, sputtering deposition, coating, spray-coating, or chemical plating may be employed to form the first sacrifice layer 14 from any of a variety of other sacrifice materials.

Except strippable photoresist for the second sacrifice layer 16, laser processing, machining process, or hot compression molding process may be employed to form the second sacrifice layer 16 from any of a variety of other strippable materials.

Further, chemical plating may be employed to substitute for the aforesaid electro forming process. Alternatively, metal deposition such as vapor deposition or sputtering deposition, or conducting material filling-in technique may be employed as a substitute.

Further, laser process, machining process, or hot compression molding process may be employed to substitute for lithography in forming the dielectric layer, achieving the effect of the present invention of using non-etching techniques.

Further, the probe body metal layers according to this embodiment can be formed of one same metal material. Alternatively, these probe body metal layers can be formed of different conducting materials containing different metals or compound materials of good electricity conducting characteristics. The probe tip can be prepared from a conducting material of high wear resistance and low stickness, thereby prolonging probe working life, improving test reliability, reducing the need of probe cleaning and maintenance, and improving test efficiency.

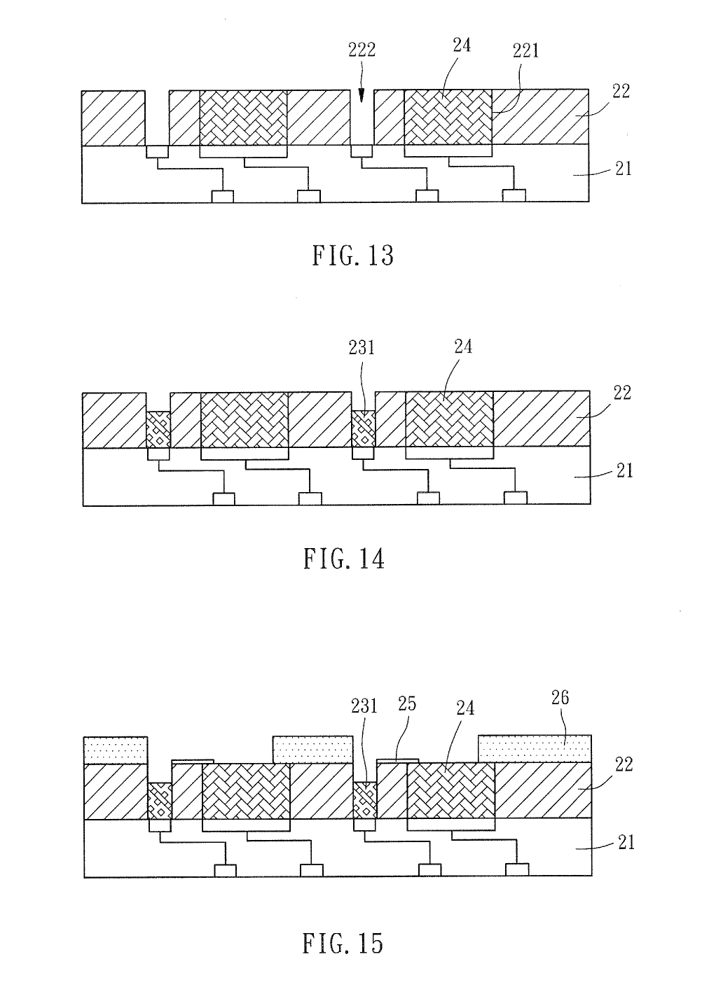

FIGS. 13-18 illustrate a method of making an electrical contact device in accordance with a second preferred embodiment of the present invention. According to this embodiment, the method of making the electrical contact device includes steps (a)-(f) as follows.

(a) Prepare a substrate 21 and form a dielectric layer 22 on the substrate 21 and wells 221 and connection grooves 222 in the dielectric layer 22 in the same manner as steps (a) and (b) of the aforesaid first embodiment of the present invention as shown in FIG. 13.

(b) As shown in FIG. 14, implant a first probe body metal layer 231 in the connection grooves 222 of the dielectric layer 22 and a first sacrifice layer 24 in the wells 221 of the dielectric layer 22 by means of electro forming technique, and if necessary, level the surface of the first sacrifice layer 24 to be flush with the dielectric layer 22. An elevation space is left between the first probe body metal layer 231 in the connection grooves 222 and the dielectric layer 22. Alternatively, the first probe body metal layer 231 can fill up the connection grooves 222 in a flush manner relative to the dielectric layer 22 without leaving the aforesaid elevation space. Similar to the aforesaid first embodiment, the formation of dielectric layer 22, the first sacrifice layer 24 and the first probe body metal layer 231 can be repeated once or several times till that each of these three laminated structures reaches the desired size.

(c) As shown in FIG. 15, implant a first conducting layer 25 and a second sacrifice layer 26 on the top side of the dielectric layer 22 in the same manner as the steps (d) and (e) of the aforesaid first embodiment.

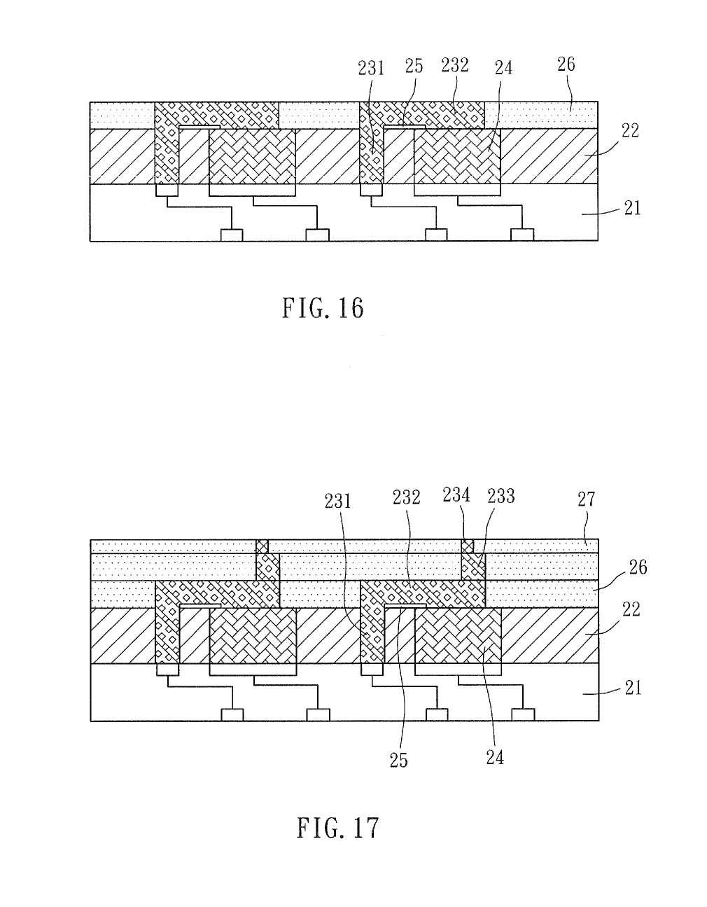

(d) Implant a second probe body metal layer 232 by means of electro forming technique with a part of the second probe body metal layer 232 formed in the space left in the connection grooves 222 and the other part of the second probe body metal layer 232 formed on the conducting layer 25 (see FIG. 16), and if necessary, level the second probe body metal layer 232 to have it be flush with the second sacrifice layer 26. The same leveling technique used in the aforesaid first embodiment can be employed to this second embodiment.

Similar to the aforesaid first embodiment, the steps (c) and (d) of this second embodiment can be repeated once or several times till that the second probe body metal layer 232 and the second sacrifice layer 26 reach the desired size. Further, except the formation of the second probe body metal layer 223 by electro forming technique, the formation of the conducting layer 15 may be omitted, and chemical plating or filling-in technique may be employed to implant a conducting substance in the probe body contour of the second sacrifice layer 26 to form the second probe body metal layer 232, and the steps may be repeated till that the second probe body metal layer 232 and the second sacrifice layer 26 reach the desired size.

(e) Repeatedly implant the third sacrifice layer 27 and the third and fourth probe body metal layers 233 and 234 to constitute the desired probe structure in the same way as the aforesaid first embodiment (see FIG. 17).

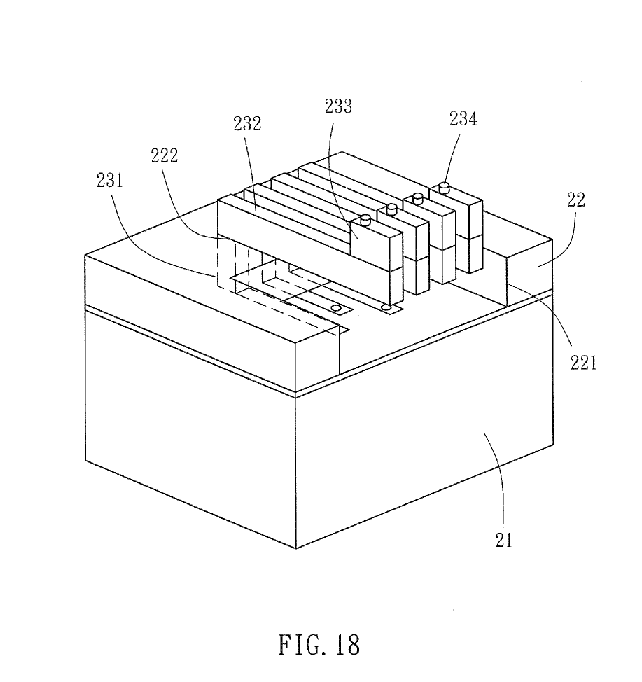

(f) Remove the first, second and third sacrifice layers 24, 26, and 27 to obtain the desired structure of electrical contact device (see FIG. 18).

According to this embodiment, the second probe body metal layer 232 has one part embedded in the connection grooves 222 and the other part exposed to the outside of the dielectric layer 22, enhancing the bonding strength between the dielectric layer and the probes that are formed of the many probe body metal layers. This embodiment prevents disconnection of the probes from the substrate after long use of the electrical contact device.

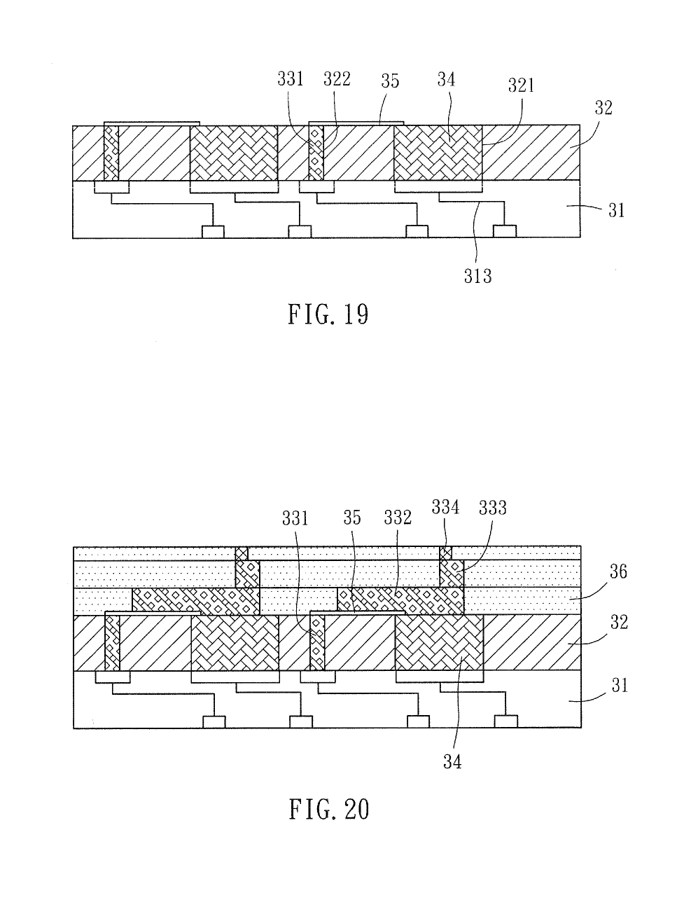

FIGS. 19-22 illustrate the steps of the method of making an electrical contact device in accordance with a third preferred embodiment of the present invention. The method of making the electrical contact device of this third embodiment includes steps (a)-(c) as follows.

(a) Prepare a substrate 31 and form a dielectric layer 32 on the substrate 31 and wells 321 and connection grooves 322 in the dielectric layer 32 and implant a first probe body metal layer 331 in the connection grooves 322 of the dielectric layer 32 and a first sacrifice layer 34 in the wells 321 of the dielectric layer 32 and a first conducting layer 35 on the top side of the dielectric layer 32 in connection between the first sacrifice layer 34 and the first probe body metal layer 331 by means of electro forming technique in the same manner as the steps (a) through (d) of the aforesaid first embodiment (see FIG. 19).

(b) Continuously lay a number of second sacrifice layers 36 and laminate a third probe body metal layer 333 and a fourth probe body metal layer 334 by electro forming technique in the same manner as the steps (e) and (f) of the aforesaid first embodiment (see FIG. 20).

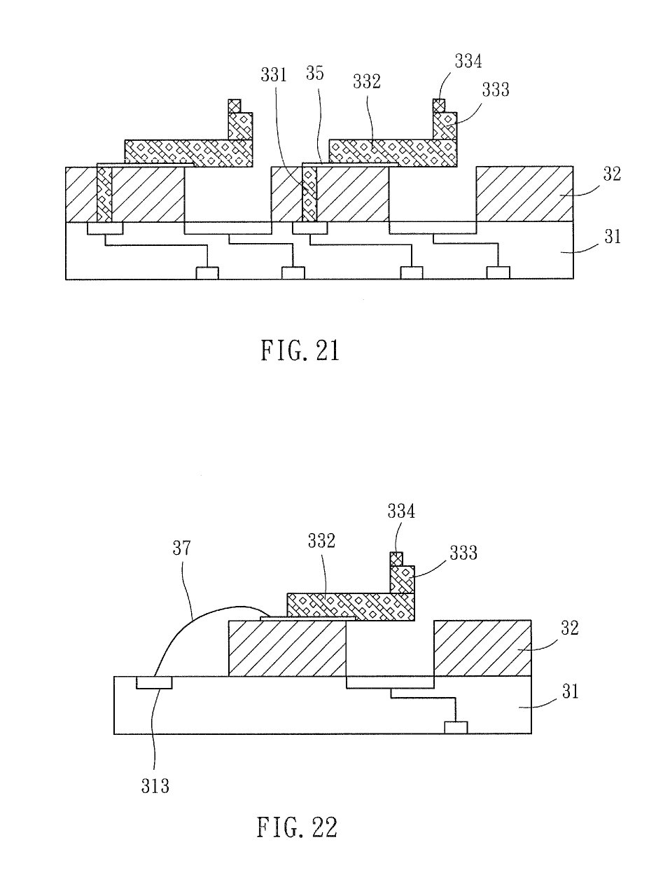

(c) Remove the second sacrifice layers 36 and the first sacrifice layer 34, thereby finishing the electrical contact device (see FIG. 21).

Same as the steps (h) and (i) of the aforesaid first embodiment, the insulative layer 18 of the aforesaid first embodiment can be formed in this embodiment and covered on the part of the first probe body metal layer 331 beyond the first sacrifice layer 34 to enhance the adhesion force between the first probe body metal layer 231 and the dielectric layer 32, improving the reliability of the probe structure.

Further, same as the aforesaid first embodiment, the first, second, third and fourth probe body metal layers 331-334 can be made subject to the desired size by means of repeating the sacrifice layer and metal layer formation procedures, and leveled, if necessary. Like the description of the aforesaid first embodiment, alternative manufacturing processes that achieve this object can also be selectively employed as a substitute.

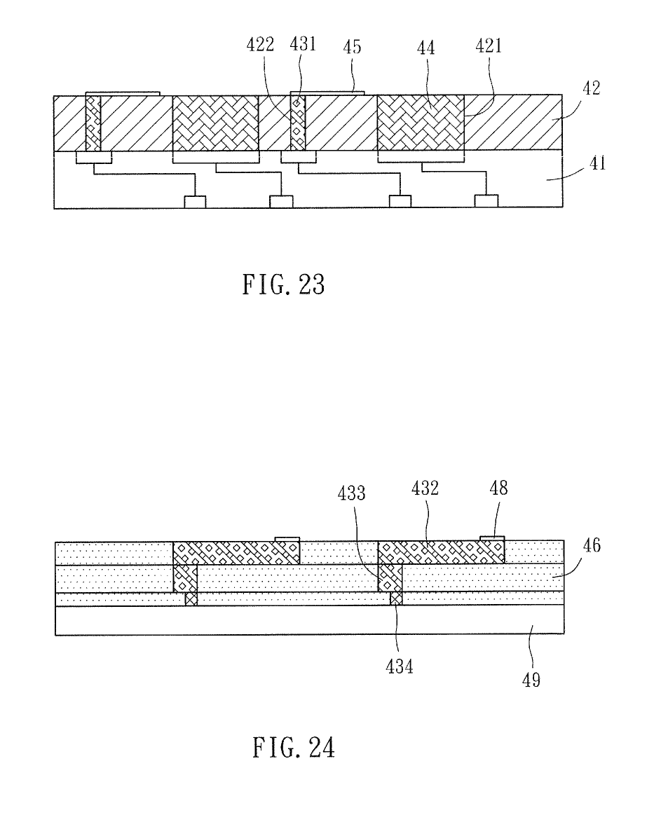

FIGS. 23-26 illustrate the steps of the method of making an electrical contact device in accordance with a fourth preferred embodiment of the present invention. The method of this fourth embodiment includes steps (a)-(d) as follows.

(a) Prepare a substrate 41 and form a dielectric layer 42 on the substrate 41 and wells 421 and connection grooves 422 in the dielectric layer 42 and implant a first probe body metal layer 431 in the connection grooves 422 of the dielectric layer 42 and a first sacrifice layer 44 in the wells 421 of the dielectric layer 42 and a first conducting layer 45 on the top side of the dielectric layer 42 in connection with the first probe body metal layer 431 by means of electro forming technique in the same manner as the steps (a) through (d) of the aforesaid first embodiment (see FIG. 23).

(b) Prepare a temporary substrate 49, and continuously lay a number of second sacrifice layers 46 on the temporary substrate 49, and then laminate a fourth probe body metal layer 434, a third probe body metal layer 433 and a second probe body metal layer 432 by means of electroforming technique, and if necessary, lay a second conducting layer 48 on the second probe body metal layer 432 for bonding (see FIG. 24).

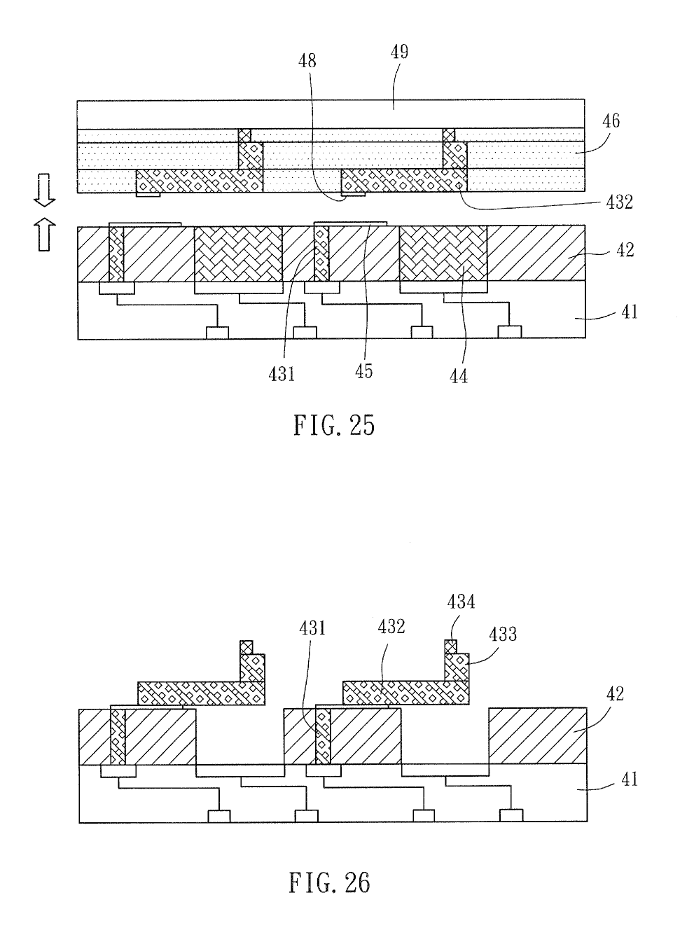

(c) Bond the first conducting layer 45 at the substrate 41 to the second conducting layer 48 at the temporary substrate 49 if the second conducting layer 48 is made, or bond the second probe body metal layer 432 to the first conducting layer 45 or the first probe body metal layer 431 directly if the second conducting layer 48 is not made (see FIG. 25). Similarly, the first probe body metal layer 431 may be directly bonded to the second conducting layer 48 or the second probe body metal layer 432 if the first conducting layer 45 is not made.

(d) Remove the second sacrifice layers 46, the temporary substrate 49 and the first sacrifice layer 44, thereby finishing the electrical contact device (see FIG. 26).

In an alternate form of the fourth embodiment, the second probe body metal layer 432 and the surrounding sacrifice layer can be formed on the dielectric layer 42 immediately after step (a), and the formation of the second probe body metal layer 432 and its surrounding sacrifice layer is eliminated from above-mentioned step (b) and replaced by bonding the second probe body metal layer 432 and the third probe body metal layer 433 to constitute the main body for each probe. The second probe body metal layer 432 and the third probe body metal layer 433 may be bonded together through or without through a conducting layer.

In another alternate form of the fourth embodiment, the second and third probe body metal layers 432 and 433 and the related surrounding sacrifice layers can be formed on the dielectric layer 42 immediately after step (a), the fourth probe body metal layer 434 and its surrounding sacrifice layer are formed in step (b), and then the third probe body metal layer 433 and the fourth probe body metal layer 434 are bonded together to constitute the main body for each probe. The third probe body metal layer 433 and the fourth probe body metal layer 434 may be bonded together through or without through a conducting layer.

In still another alternate form of the fourth embodiment, the formation of the first sacrifice layer 44 is eliminated from step (a), and the first probe body metal layer at the substrate is directly bonded to the probe body metal layers at the temporary substrate.

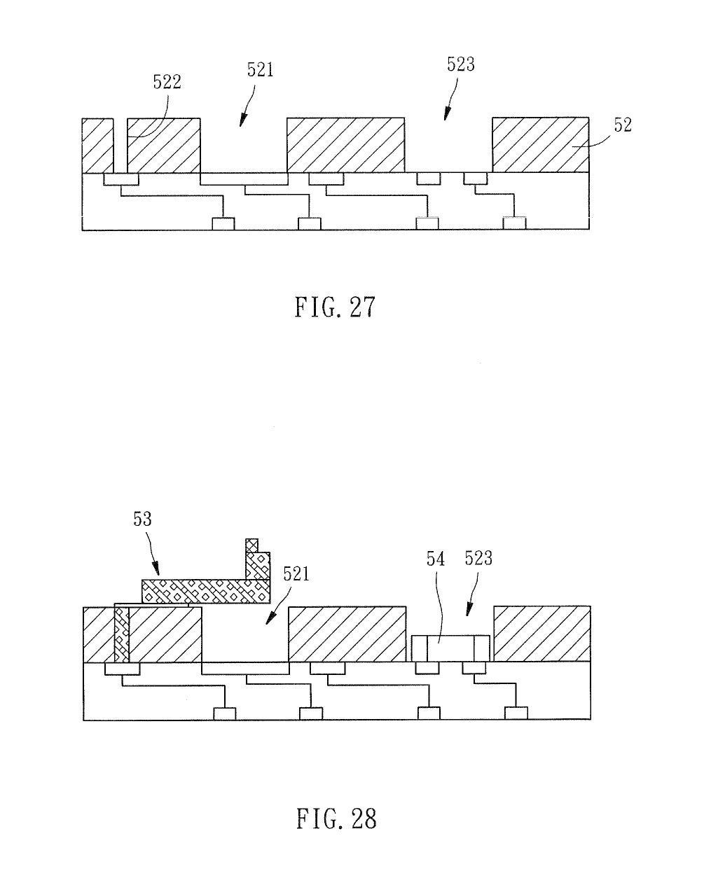

FIGS. 27 and 28 illustrate a method of making an electrical contact device in accordance with a fifth preferred embodiment of the present invention. This fifth embodiment is substantially similar to the aforesaid various embodiments with the exception that at least one electronic device mounting groove 523 is formed on the dielectric layer 52 during the formation of the wells 521 and the connection grooves 522 (see FIG. 27), so that electronic device(s) 54 can be connected to the substrate 51 and disposed in the at least one mounting groove 523 by welding or any other technique after formation of the probe body metal layers 53 and removal of the sacrifice layers (not shown).

In either of the aforesaid various embodiments, the process of forming the first metal layer 131, 231, 331, 431 may be omitted. In this case, bonding wires 37 are employed to electrically connect the conducting layer 35 and the circuit layouts 313 of the substrate 31 (see FIG. 22). Alternatively, the second metal layer 132, 232, 332, or 432 may be connected to the circuit layouts 313 by bonding wires.

Similar to the aforesaid first embodiment, lithography technology may be used in either of the other embodiments to form an insulative layer to partially cover the probes, enhancing the bonding strength between the probes and the dielectric layer. This insulative layer can be formed by means of semiconductor manufacturing process, masking with spray-coating, coating, vapor deposition, sputtering deposition, or electro deposition coating techniques.

By means of the method of making the electrical contact device in accordance with either of the various embodiments of the present invention, probes are formed of multiple probe body metal layers, and wells are formed on the dielectric layer to provide an elastic deformation space for each probe. The manufacturing process of the invention requires a less number of processing steps when compared to the conventional method of forming the wells in the substrate by means of etching technology. Further, the invention imparts good reworkability that helps improvement of yield rate in manufacturing electrical contact devices. Further, because of the use of non-etching techniques to form the desired wells and connection grooves, the invention eliminates the drawbacks of being not easy to control and high manufacturing cost of the conventional methods that employ etching steps.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A method of making an electrical contact device, comprising the steps of:
(a) preparing a substrate;
(b) forming a dielectric layer on the substrate and forming a well on the dielectric layer;
(c) forming a first sacrifice layer in the well;
(d) forming a second sacrifice layer on the dielectric layer and the first sacrifice layer and defining a probe body contour;
(e) forming a first probe body metal layer in the probe body contour;
(f) repeating steps (d) and (e) at least one time to form a laminated electrical contact structure having a probe body and a probe tip; and
(g) removing the first sacrifice layer and the second sacrifice layer so as to obtain an electrical contact device including the substrate and the electrical contact structure having a part thereof disposed in the dielectric layer.

2. The method as claimed in claim 1, wherein a connection groove is formed on the dielectric layer in communication with a surface of the substrate in step (b).

3. The method as claimed in claim 2, wherein a second probe body metal layer is implanted in the connection groove for electrically connecting the first probe body metal layer to a circuit on the surface of the substrate in step (c).

4. The method as claimed in claim 3, further comprising a step of leveling the second probe body metal layer, the first probe body metal layer and the first sacrifice layer in a flush manner.

5. The method as claimed in claim 3, further comprising a step of forming a second conducting layer on the second probe body metal layer and an adjacent part of the dielectric layer.

6. The method as claimed in claim 5, wherein the second conducting layer is formed by means of one of the techniques of semiconductor manufacturing process and pattern coating process.

7. The method as claimed in claim 3, wherein the second probe body metal layer is formed by means of one of the techniques of electroforming process, semiconductor manufacturing process, chemical plating and conducting material filling-in process.

8. The method as claimed in claim 1, further comprising a step of leveling the first sacrifice layer and the dielectric layer to have the first sacrifice layer be flush with the dielectric layer after step (c).

9. The method as claimed in claim 1, further comprising a step of leveling the first probe body metal layer and the second sacrifice layer in a flush manner after step (e).

10. The method as claimed in claim 1, further comprising a step of forming a first conducting layer on a surface of the dielectric layer and a part of the first sacrifice layer before step (d).

11. The method as claimed in claim 10, wherein the first conducting layer is formed by means of one of the techniques of semiconductor manufacturing process and pattern coating process.

12. The method as claimed in claim 10, further comprising a step of electrically connecting the first conducting layer to a circuit on a surface of the substrate with a bonding wire.

13. The method as claimed in claim 1, wherein the well in step (b) is formed by means of one of the techniques of lithography, laser processing, hot compression molding, and machining process.

14. The method as claimed in claim 1, wherein the first sacrifice layer in step (c) is formed by means of one of the techniques of electroforming process, chemical plating, and sacrifice material filling-in process.

15. The method as claimed in claim 1, wherein the second sacrifice layer is formed by means of one of the techniques of lithography, laser processing, hot compression processing process, and machining process to define the probe body contour.

16. The method as claimed in claim 1, wherein the probe body and the probe tip of the laminated electrical contact structure are formed of different conducting materials.

17. The method as claimed in claim 1, wherein the first probe body metal layer is formed by means of one of the techniques of electroforming process, semiconductor manufacturing process, chemical plating, and conducting material filling-in process.

18. The method as claimed in claim 1, further comprising a step of forming an insulative layer on the dielectric layer; wherein first probe body metal layer is partially covered by the insulative layer.

19. The method as claimed in claim 18, wherein the insulative layer is formed by means of lithography after formation of the probe body after step (e) and after removal of the second sacrifice layer around the probe body, and a third sacrifice layer is filled in a crevice of the insulative layer after the formation of the insulative layer.

20. The method as claimed in claim 19, wherein the third sacrifice layer is formed by means of the techniques of semiconductor manufacturing process, electroplating, chemical plating, and sacrifice material filling-in process.

21. The method as claimed in claim 18, wherein the insulative layer is formed by means of masking and spray-coating technique after formation of the probe body after step (e) and after removal of the second sacrifice layer around the probe body, and a third sacrifice layer is filled in a crevice of the insulative layer after the formation of the insulative layer.

22. The method as claimed in claim 21, wherein the third sacrifice layer is formed by means of the techniques of semiconductor manufacturing process, electroplating, chemical plating, and sacrifice material filling-in process.

23. The method as claimed in claim 1, wherein the substrate has an electric circuit formed therein and electric contacts formed on a surface thereof.

24. The method as claimed in claim 19, further comprising a step of electrically connecting the substrate to an external probe card set.

25. The method as claimed in claim 1, further comprising a step of forming a mounting groove on the dielectric layer for the mounting of an electronic device.

26. The method as claimed in claim 1, further comprising a step of electrically connecting the first probe body metal layer to a circuit on a surface of the substrate by a bonding wire.

27. A method of making an electrical contact device, comprising the steps of:
(a) providing a substrate;
(b) forming a dielectric layer on the substrate and forming a well on the dielectric layer; and
(c) bonding a probe to the dielectric layer in a manner that a part of the probe suspends above the well.

28. The method as claimed in claim 27, wherein the substrate has an electric circuit formed therein and electric contacts formed on a surface thereof.

29. The method as claimed in claim 27, wherein a mounting groove is formed for the mounting of an electronic device in step (b).

30. The method as claimed in claim 27, wherein a connection groove is formed on the dielectric layer in communication with a surface of the substrate in step (b).

31. The method as claimed in claim 30, wherein a first metal layer is formed in the connection groove for connecting the probe.

32. The method as claimed in claim 31, wherein the first metal layer is formed by means of one of the techniques of electroforming process, semiconductor manufacturing process, chemical plating, and conducting material filling-in process.

33. The method as claimed in claim 27, wherein the dielectric layer is provided on a surface thereof with a conducting layer for the bonding of the probe in step (c).

34. The method as claimed in claim 27, wherein the well in step (b) is formed by means of one of the techniques of lithography, laser processing, hot compression processing process, and machining process.

35. The method as claimed in claim 27, wherein the probe is made by following steps:
(a) providing a temporary substrate;
(b) forming a sacrifice layer on the temporary substrate and defining a probe body contour;
(c) forming a probe body metal layer in the probe body contour;
(d) repeating steps (b) and (c) to form the probe;
(e) bonding the probe body metal layer at the temporary substrate to the dielectric layer; and
(f) removing the sacrifice layer and separating the temporary substrate from the substrate.

36. The method as claimed in claim 35, further comprising a step of leveling the sacrifice layer and the probe body metal layer in a flush manner after step (c) of claim 35.

37. The method as claimed in claim 35, wherein probe includes multiple probe body metal layers, which are formed of different conducting materials.

38. The method as claimed in claim 35, wherein the probe body metal layer of the probe is formed by means of one of the techniques of electroforming process, semiconductor manufacturing process, chemical plating, and conducting material filling-in process.

39. The method as claimed in claim 35, wherein the sacrifice layer is formed by means of one of the techniques of lithography, laser processing, hot compression processing process, and machining to define the probe body contour.

40. The method as claimed in claim 27, wherein the dielectric layer is disposed with an insulative layer covering partially the first probe body metal layer.

41. The method as claimed in claim 40, wherein the insulative layer is formed by means of one of the techniques of semiconductor manufacturing process and masking and spray-coating process.

42. The method as claimed in claim 27, wherein a bonding wire is electrically connected the probe to the substrate.

43. An electrical contact device of a probe card, comprising:
a substrate having a surface dielectric layer;
a well recessed on the surface dielectric layer and forming at least one wall abutting with the surface, the sat least one wall being disposed with at least one locating portion; and
at least one probe having a first end set in the at least one locating portion of the substrate, and a second end extending toward the well.

44. The electrical contact device as claimed in claim 43, wherein the at least one locating portion is a recess formed in the at least one wall and the surface.

45. The electrical contact device as claimed in claim 43, wherein the at least one locating portion has a part cut through the surface dielectric layer in communication with the surface of the substrate.

46. The electrical contact device as claimed in claim 45, wherein the part of the locating portion that cut through the dielectric layer in communication with the surface of the substrate receives a part of the at least one probe and the at least one probe is electrically connected with a circuit on the surface of the substrate.
